(19) United States
(12) Patent Application Publication
(10) Pub. No.: US 2014/0125352 A1
(43) Pub. Date: May 8, 2014

(54) APPARATUS, SYSTEM, METHOD AND COMPUTER PROGRAM FOR TESTING AN ELECTRICAL CONNECTION

(71) Applicants: Thomas Franke, Laupheim (DE); Tim Sobig, Reutlingen (DE)

(72) Inventors: Thomas Franke, Laupheim (DE); Tim Sobig, Reutlingen (DE)

(73) Assignee: NOKIA CORPORATION, Espoo (FI)

(21) Appl. No.: 14/129,279

(22) PCT Filed: Jul. 5, 2011
(86) PCT No.: PCT/IB2011/052975

§ 371 Date: Dec. 24, 2013

(51) Int. Cl. H01R 13/66; G01R 31/04

(52) U.S. Cl. CPC H01R 13/6683; G01R 31/043
USPC 324/538; 439/489; 439/884

(57) ABSTRACT

An apparatus comprising: a first terminal; and a second terminal; wherein: the first terminal is configured to electrically couple with a respective first terminal of a second apparatus when the apparatus and said second apparatus are in either of a first mated condition and a second mated condition; and the second terminal is configured: to electrically couple with a respective second terminal of said second apparatus when the apparatus and said second apparatus are in the first mated condition, and to electrically decouple from said respective second terminal of said second apparatus when the apparatus and said second apparatus are in a second mated condition.

### FIELD OF THE INVENTION

Embodiments of the present invention relate to an apparatus, system, method and computer program. In particular, though without prejudice to the foregoing, various embodiments relate to electrical connectors.

### BACKGROUND TO THE INVENTION

Devices, particularly those which involve electrical modules that move with respect to one another (such as in foldable or slidable mobile phones) use connectors for making electrical power and data connections between electrical components such as printed circuit boards and electrical modules. It is important to ensure a good connectivity between mated connectors as a failure to correctly mate may cause a device to fail to function properly.

The electrical connections of two mated connectors, such as a board to board connector, in a device can be tested during assembly of the device at a factory. However, it is possible for the mated connectors to provide electrical connections and thus pass such a test in spite of being improperly mechanically mated, i.e. incorrectly mated or loosely fit. Accordingly, for such a device, after its assembly in the factory and following its packaging, transport, delivery (and use by a user) during which it might be subject to impacts, the mechanical connection may further worsen such that the connectors no longer provide electrical connections and thus the device may fail to function properly.

The listing or discussion of a prior-published document or any background in this specification should not necessarily be taken as an acknowledgement that the document or background is part of the state of the art or is common general knowledge. One or more aspects/embodiments of the present disclosure may or may not address one or more of the background issues.

### BRIEF DESCRIPTION OF VARIOUS EMBODIMENTS OF THE INVENTION

According to various, but not necessarily all, embodiments of the invention there is provided an apparatus comprising:
a first terminal ; and
a second terminal;
wherein:
   the first terminal is configured to electrically couple with a respective first terminal of a second apparatus when the apparatus and said second apparatus are in either of a first mated condition and a second mated condition; and
   the second terminal is configured:
      to electrically couple with a respective second terminal of said second apparatus when the apparatus and said second apparatus are in the first mated condition, and
      to electrically decouple from said respective second terminal of said second apparatus when the apparatus and said second apparatus are in a second mated condition.

Various embodiments of the invention provide an electrical connection between the two respective second terminals when in a first mated condition (e.g. adequately/properly/fully mechanically connected) and no electrical connection when in a second mated condition (e.g. inadequately/improperly/partially mechanically connected). Accordingly, a determination of the mated condition of the apparatus and the second apparatus can be made based on determining whether or not there is an electrical connection between the two respective second terminals.

Various, but not necessarily all, embodiments of the present invention seek to provide an improved connector that enables a determination to be made of whether or not the connector is adequately mechanically connected. Advantageously, various embodiments enable a determination of an adequate mechanical connection to be made based on an electrical test.

According to various, but not necessarily all, embodiments of the invention there is provided a system comprising:
a first apparatus; and
a second apparatus;
wherein at least one of the first and second apparatuses is configured:
   to electrically couple a first terminal of the first apparatus with a respective first terminal of the second apparatus when the first and second apparatuses are in either of a first mated condition and a second mated condition;
   to electrically couple a second terminal of the first apparatus with a respective second terminal of the second apparatus when the first and second apparatuses are in the first mated condition; and
   to electrically decouple the second terminal of the first apparatus from the respective second terminal of the second apparatus when the first and second apparatuses are in a second mated condition.

According to various, but not necessarily all, embodiments of the invention there is provided a method comprising:
causing, at least in part, actions that result in testing an electrical connection between a second terminal of a first apparatus and a respective second terminal of a second apparatus, wherein:
the first apparatus comprises:
   a first terminal configured to electrically couple with a respective first terminal of the second apparatus when the first apparatus and the second apparatus are in either of a first mated condition and a second mated condition; and wherein
   the second terminal is configured:
      to electrically couple with the respective second terminal of the second apparatus when the apparatus and the second apparatus are in the first mated condition, and
      to electrically decouple from the respective second terminal of the second apparatus when the first apparatus and the second apparatus are in a second mated condition.

According to various, but not necessarily all, embodiments of the invention there is provided an apparatus comprising:
a first means for electrically coupling with a respective first electrically conductive means of a second apparatus when the apparatus and said second apparatus are in either of a first mated condition and a second mated condition; and
a second means for electrically coupling with a respective second electrically conductive means of said second apparatus when the apparatus and said second apparatus are in the first mated condition, and wherein
the second means is configured to electrically decouple from said respective second electrically conductive means of said second apparatus when the apparatus and said second apparatus are in the second mated condition.

### BRIEF DESCRIPTION OF THE DRAWINGS

For a better understanding of various examples of embodiments of the present invention reference will now be made by way of example only to the accompanying drawings in which:

FIG. 1 schematically illustrates an apparatus of an embodiment of the present invention;

FIG. 2A schematically illustrates the apparatus of FIG. 1 in a first mated condition;

FIGS. 2B and 2C schematically illustrate the apparatus of FIG. 1 in a second mated condition;

FIG. 3A and 3B schematically illustrate an apparatus of a further embodiment of the present invention;

FIGS. 4A and 4B illustrate further embodiments of the present invention;

FIGS. 5A to 5C schematically illustrate cross sectional views of the embodiment shown in FIG. 4A in various mated conditions;

FIGS. 6A and 6B schematically illustrate cross sectional views of an embodiment of the present invention;

FIGS. 7A and 7B schematically illustrate cross sectional views of an embodiment of the present invention;

FIG. 8 schematically illustrates a further embodiment of the present invention;

FIG. 9 schematically illustrates a flow chart of a method of an embodiment of the present invention; and

FIG. 10 schematically illustrates an apparatus of a further embodiment of the present invention.

### DETAILED DESCRIPTION OF VARIOUS EMBODIMENTS OF THE INVENTION

The figures illustrate an apparatus (100) comprising:
a first terminal (101); and
a second terminal (102) ;
   wherein:
the first terminal (101) is configured to electrically couple with a respective first terminal (101′) of a second apparatus (100′) when the apparatus (100) and said second apparatus (100′) are in either of a first mated condition (200) and a second mated condition (201a, 201b); and
the second terminal (102) is configured:
   to electrically couple with a respective second terminal (102′) of said second apparatus (100′) when the apparatus (100) and said second apparatus (100′) are in the first mated condition (200), and
   to electrically decouple from said respective second terminal (102′) of said second apparatus (100′) when the apparatus (100) and said second apparatus (100′) are in the second mated condition (201a, 201b).

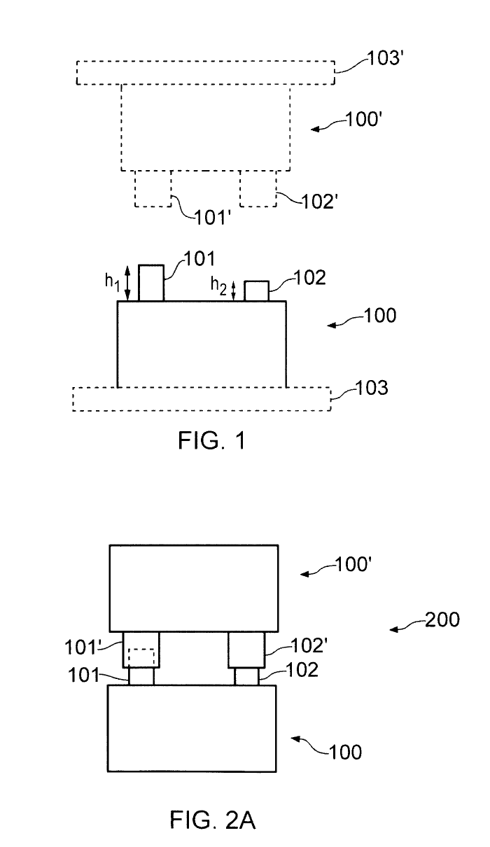

FIG. 1 schematically illustrates a cross-sectional view of an apparatus 100 of an embodiment of the present invention.

The component blocks of FIG. 1 are functional and the functions described may or may not be performed by a single physical entity as described with reference to FIG. 1. Only the functional components that are necessary for describing the operation of the apparatus are shown. Each of the components described below may be any device, means or circuitry configured to perform the corresponding functions of the respective components as described in greater detail below. The apparatus 100 may be provided as part of a module. As used here ‘module’ refers to a unit or apparatus that excludes certain parts/components that would be added by an end manufacturer or a user.

The apparatus 100 may be a connector for making electrical connections. For example, the apparatus may be a connector connected to an electrical component 103 (shown in outline). The components may be, for example, a printed circuit board, printed wired board, flexible printed circuit, electrical module or device. The apparatus 100 is configured to mate with and electrically connect with another apparatus 100′ (shown in outline) such as another connector. The apparatus 100′ may itself be connected to another electrical component 103′. The two apparatuses are configured such that, when mated together they can convey electrical signals, data or power between their respective components.

The connector 100 comprises a first terminal 101 and a second terminal 102. The terminals are electrically conductive means that provide an electrical contact point for engaging and electrically coupling with respective terminals 101′ and 102′ of the other connector 100′ when in a mated condition. The terminals may, for example, be pins or contacts. The first terminal has dimensions different to that of the second terminal. For example, a contact height h1 (i.e. a height at which an electrical contact is made with its respective terminal 101′) of the first terminal 101 is greater than a contact height h2 of the second terminal 102. The contact height of the second terminal 102 is configured such that electrical contact of the second terminal 102 with its respective terminal 102′ is only provided when the first and second connectors are adequately or correctly mated together. Advantageously, providing a second terminal 102 that is shorter that the first terminal 101 ensures that if the second terminal is correctly connected then the first terminal is also correctly connected.

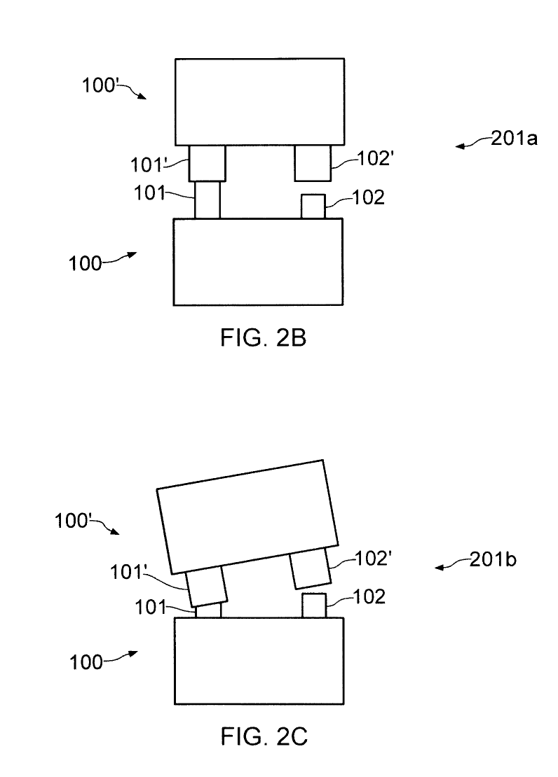

FIG. 2A schematically illustrates the connectors in a first mated condition 200. The first mated condition may comprise the first and second terminals 101 102 engaging with their respective first and second terminals 101′ 102′ so as to provide an electrical connection therebetween as well as a mechanical connection. The first mated condition may comprise a mechanical connection wherein the connectors are sufficiently secure, i.e. fully or properly mechanically mated together such that an adequate mechanical mate is provided.

The first terminal 101 is configured to electrically couple with its respective first terminal 101′ of the other connector 100′ when the two connectors are in the first mated condition 200. The second terminal 102 is also configured to electrically couple with its respective second terminal 102′ of the other connector 100′ when the two connectors are in the first mated condition 210.

It will be appreciated that the respective first and second terminals 101′ and 102′ may be configured to at least partly receive therein the first and second terminals 101 and 102 as is shown. Alternatively, the terminals 101 102 may be configured so as to physically overlap and touch the other terminals 101′ 102′.

FIGS. 2B and 2C schematically illustrate the connectors 100 100′ in a second mated condition 201a and 201b respectively. Such a mated condition may comprise a mechanical mate wherein the connectors are insufficiently secure, e.g. only partially or improperly mechanically mated together.

FIG. 2B shows the connectors partially mechanically mated together 201a, wherein one connector has not been fully inserted into the other. FIG. 2C shows the connectors improperly mechanically mated together 201b, wherein one connector has been inserted at an oblique angle with regards to the connector such that the connectors are askew and improperly aligned.

The first terminal 101 is configured to electrically couple with its respective first terminal 101′ of the other connector 100′ when the two connectors are in the second mated condition 201a, 201b. However, the second terminal 102 is configured such that it is electrically decoupled, i.e. disconnected, from its respective second terminal 102′ of the other connector 100′ when the two connectors are in the second mated condition.

Accordingly, whilst the first terminal 101 and its respective first terminal 101′ are in electrical contact when the connectors are either properly and improperly mated, the second terminal 102 and its respective second terminal 102′ are only in electrical contact when the connectors are properly mated. When the connectors are improperly mated, the second terminal 102 and its respective second terminal 102′ are electrically disconnected/decoupled. Advantageously, this enables an improper mechanical connection of the connectors to be detected by testing the electrical connection between second terminal 102 and its respective second terminal 102′.

The above mentioned electrical connectivity of the first and second terminals 101, 102 in the first and second mating conditions may be provided by the second terminal 102 being dimensioned differently from that of the first terminal 101. For example, the second terminal 102 could be of a different size and/or shape to that of the first terminal 101 such that its electrical conductivity with its respective second terminal 102′ of the other connector has the above mentioned properties, namely being electrically connected when in the first mated condition and electrically disconnected when in the second mated condition.

In order to show more simply the first and second mating conditions, the second connector 100′ is shown as having terminals 101′ 102′ which project from a housing/base of the connector. It will be appreciated that the two connectors may be configured as a “male” and “female” connector respectively, i.e. wherein the male connector has protruding terminals whilst the female connector has recessed terminals that are configured to define a cavity to receive the protruding terminals of the male connector.

In the above described embodiment the connector 100 can be considered to be a male connector whose size and dimension of its second protruding terminal 102 is different (i.e. has a lower contact point height) to that of its first protruding terminal 101. However, it is to be appreciated that alternatively a female connector could be provided in which the dimension of a recessed second terminal is different from that of a first recessed terminal, e.g. the depth of the recessed second terminal contact point may be lower than the depth of the recessed first terminal's contact point. In either scenario, the dimensions of the second terminal are configured so as to provide the appropriate electrical coupling for first and second mated conditions as set out above.

Whilst only the first connector 100 is shown having a second terminal 102 configured as described above, it will be appreciated that in a system of two connectors, either one or both of the connectors may be provided with such second terminals.

Each connector may further be provided with an additional mechanism for mechanically coupling the connectors together, such as a snap-fit arrangement. The first mated condition may correspond to the first and second connectors being fastened by the mechanical mechanism, e.g. snapped together. Alternatively, no such separate fastening device may be used and instead frictional forces between inter-engaged terminals may be relied on as securing means.

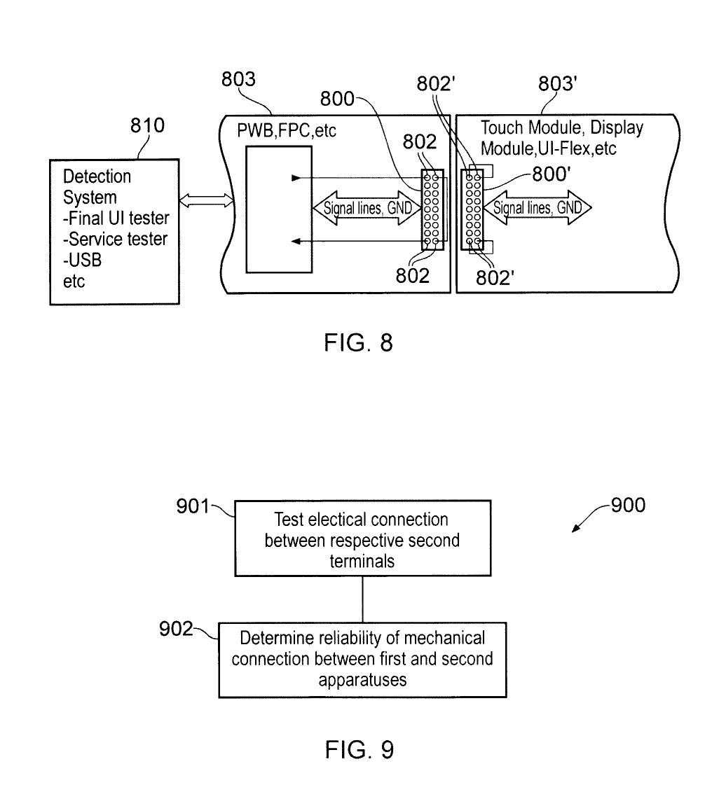

In one embodiment, the first terminal 101 may be a “signal pin”, i.e. a terminal for conveying signals/data/voltages from a data line from one electrical component 103 to another component 103′. The second terminal may be a “detection pin”. Such a pin may not be used to convey signals between the components but could instead be dedicated to providing part of a detection circuit for detecting whether or not there is a suitable mechanical connection between connectors (see FIG. 8 for further details). Such a detection pin may be attached to circuitry configured to determine whether or not there is an electrical connection between the detection pin 102 and its respective terminal 102′. However, in an alternative embodiment the detection pin may also additionally used as a signal pin to convey signals between the components 103 and 103′.

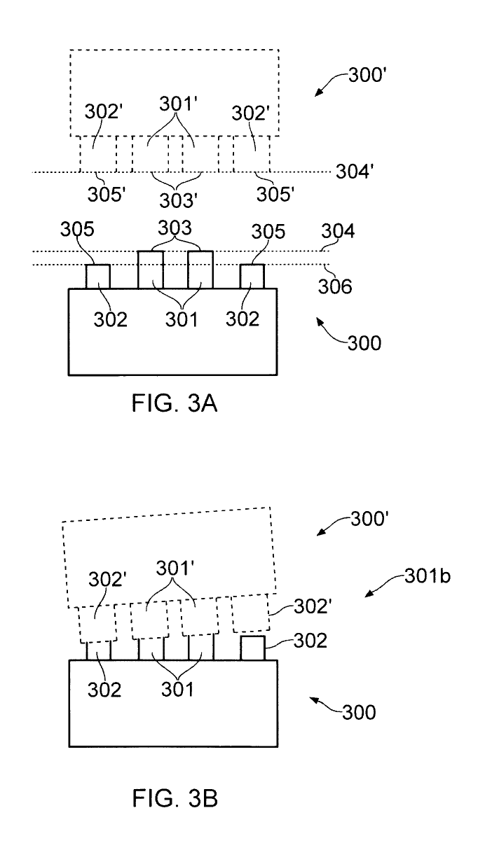

FIGS. 3A and 3B schematically illustrate a further embodiment in which there are a plurality of first terminals 301 of a first connector 300 and a plurality of respective first terminals 301′ of a second connector 300′. Likewise, there are a plurality of second terminals 302 of the first connector and a plurality of respective second terminals 302′ of the second connector. The two connectors and their respective terminals are configured so as to be able to mate with one another.

The plurality of first terminals 301 may be signal pins, whereas the plurality of second terminals 302 may be detection pins.

The dimensions of each of the signal pins 301 may be substantially uniform, i.e. they all have the same size and/or shape. The dimensions of each of the detection pins 302 likewise may be substantially uniform. However, the dimensions of each of the signal pins 301 are different to the dimensions of each of the detection pins 302. By contrast, the dimensions of the plurality of first terminals 301′ of the other connector 300 are the same as the dimensions of the plurality of second terminals 302′ of the other connector. Advantageously, no modification of the terminals 301′ 302′ of the other connector 300′ is required as they are all uniform. Accordingly, a standard connector could be used for the other connector 300′.

Each signal pin 301 comprises an electrical contact point 303, e.g. an uppermost surface of the signal pin, and each electrical contact point may be located substantially along a first plane 304. Likewise, each detection pin 302 comprises an electrical contact point 305 and each such electrical contact point 305 may be located substantially along a second plane 306 which is different to the first plane 304.

Each terminal of the plurality of respective first terminals 301′ comprises at least one electrical contact point 303′, and each such electrical contact point may be located substantially along a third plane 304′. Likewise, each terminal of the plurality of respective second terminals 302′ comprises at least one electrical contact point 305′, and each such electrical contact point may be located substantially along the same third plane 304′.

FIG. 3B shows the connectors 300 and 300′ in a second mated condition 301b wherein one connector is obliquely inserted into the other such that they are askew. In such a mated condition, at least one of the detection pins 302 is electrically disconnected from its respective terminal 302′ (as is shown for the right-hand side detection pin).

Advantageously, the provision of two or more detection pins 302 enables the detection of a greater range of angles of improper mechanical connections, e.g. torsions in a greater range of directions. For example, if the connector of FIGS. 3A and 3B were only provided with the left-hand detection pin (and not also provided with the right-hand detection pin), the leftwardly askew mechanical connection of FIG. 3B would not be detected since the left-hand detection pins would be in electrical contact with its respective terminal. Likewise, if the connector were only provided with the right-hand detection pin and the connectors were to be rightwardly askew, such an improper mechanical connection would not be detected. Having two detection pins along the same line enables detection of an improper mechanical mate due to a twisting/rotation about an axis perpendicular to the line.

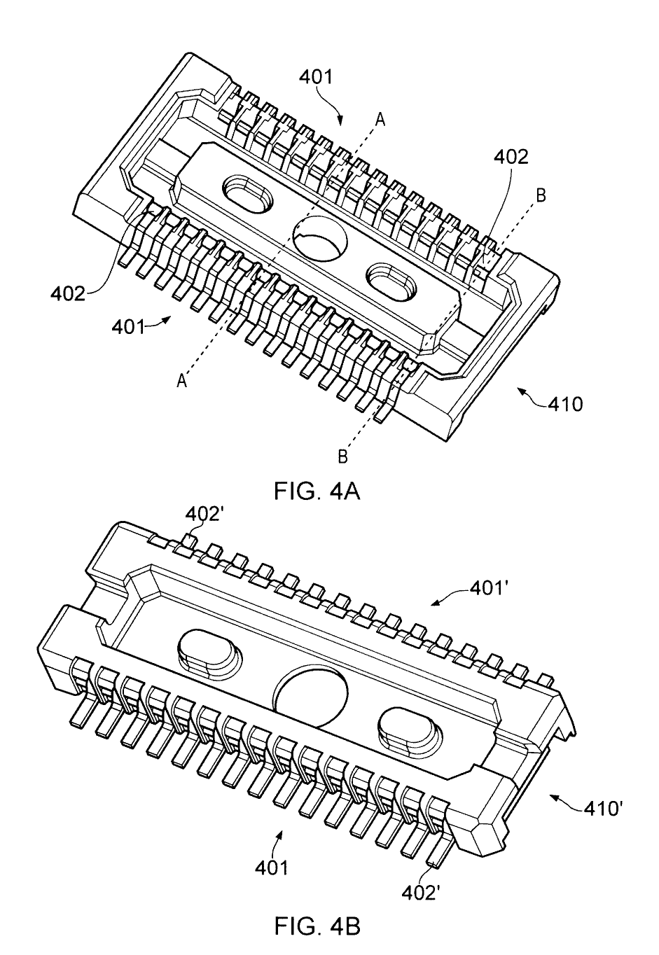

FIG. 4A illustrates a further embodiment of the present invention in the form of a female version of a board to board connector 410, whilst FIG. 4B illustrates a male board to board connector 410′ for inserting into and mating with the female board to board connector 410.

In each connector, two columns and 15 rows of terminals are provided. Two of the terminals 402 for the connector 410 are detection pins having an electrical contact point which is lower than the electrical contact points for the remaining signal pins 401. The other connector 410′ comprises two columns and 15 rows of respective terminals 401′ 402′ all of which are uniform.

As will be readily appreciated, the connectors could be provided with various numbers of signal pins and detections pins in various arrangements, for example one could have a connector comprising:
10 pins (6 signal pins+4 detection pins)
28 pins (24 signal pins+4 detection pins)
34 pins (30 signal pins+4 detection pins)
44 pins (40 signal pins+4 detection pins)

Advantageously, having at least two detection pins along a first line and at least two detection pins along a second orthogonal line enables detection of an improper mechanical mate due to a rotation/twisting of one of the connectors.

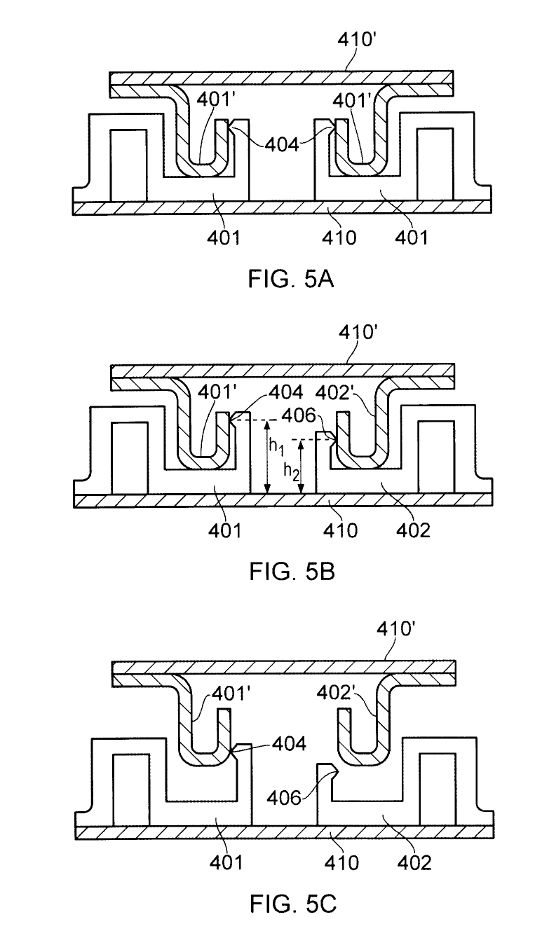

FIG. 5A provides a cross sectional cut through along the line A-A of the connector 410 of FIG. 4A when in a first mated condition with the connector 410′ of FIG. 4B. This shows a side-on view of a configuration of a row of signal pins 401 of the connector 410 as well as the respective signal pins 401′ of the connector 410′ of FIG. 4B.

FIG. 5B provides a cross sectional cut through along the line B-B of the connector 410 of FIG. 4A when in a first mated condition with the connector 410′ of FIG. 4B. This shows a side-on view of a configuration of a row of pins of the connector 410. One of the pins of the row is a signal pin 401, whilst the other pin is a detection pin 402. The detection pin is dimensioned differently to that of the signal pin. In particular, a height h2 of its electrical contact point 406 is lower than the height h 1 of the signal pin's electrical contact point 404.

FIG. 5C provides a cross sectional cut through along the line B-B of the connector 410 of FIG. 4A when in a second mated condition with the connector 410′ of FIG. 4B. In this second mated condition, the connectors are only partially mechanically mated together since they are not fully engaged or inserted into one another. Whilst the signal pin 401 and its respective terminal 401′ remain in electrical contact at the electrical contact point 404, the detection pin 402 is not in electrical contact with its respective terminal 402′ at the electrical contact point 406.

Preferably, the size shape and number of electrical contact points of the detection pins of a first connector and their respective pins of a second connector are configured to as to provide:
an electrical connection between the pins up to a degree of mechanical connection that corresponds to a sufficiently secure mechanical mate, and
no electrical connection between the pins after a degree of mechanical connection that corresponds to an insufficiently secure mechanical mate.

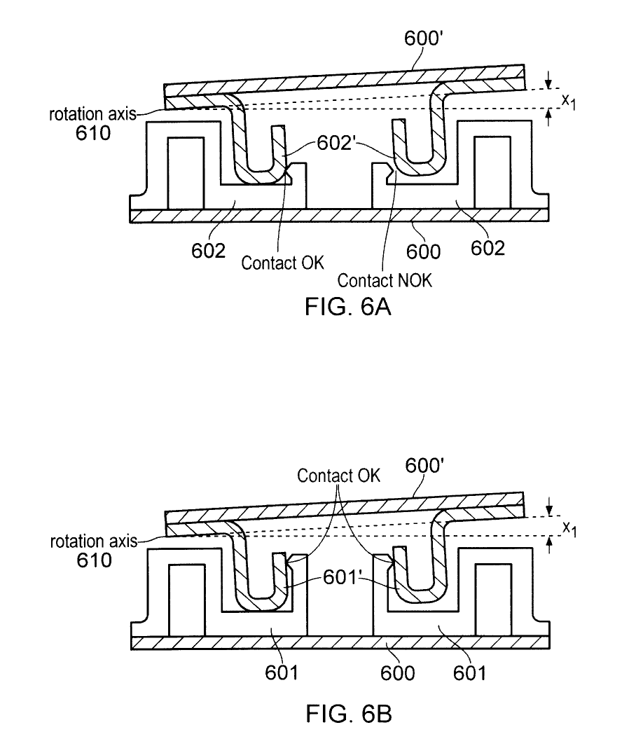

FIGS. 6A and 6B schematically illustrate cross sectional views of a further embodiment of the present invention.

FIGS. 6A and 6B provide cross sectional side-on views of two different rows of pins of a first connector 600 when in a third mated condition with a second connector 600′. In FIG. 6A (and unlike the embodiment shown in FIGS. 5B and 5C) both of the pins of its row are detection pins 602. In FIG. 6B, both of the pins of its row are signal pins 601 (which have a size different to the detection pins 602 and an electrical contact point 604 higher than an electrical contact point 606 of the detection pins of FIG. 6A).

In the third mated condition, the second connector 600′ is not fully/properly mechanically connected to the first connector 600 but is inserted obliquely with a rotation an angle x1, for example an angle less that 5 degrees such as 2.5 degrees, about a rotation axis 610. In FIG. 6B, both signal pins 601 are in electrical contact with their respective pins 601′ of the second connector 600′, as indicated with “contact OK”. In FIG. 6A, whilst the left-hand side detection pin 602 is in electrical contact with its respective pin 602′ via its electrical contact point 606 as indicated with “contact OK”, the right-hand sign detection pin 602 is not in electrical contact with its respective pin 602′ as indicated “contact N[ot]OK”. Accordingly, since at least one of the detection pins is not electrically connected to its respective pin, a test of the electrical connection of the detection pins would provide an indication of an improper mechanical mate.

However, in this example, the third mated condition relates to a mechanical mate that is only slightly askew, e.g. wherein the second connector is only slightly misaligned and inserted rotated at an angle x1 less that 5 degrees. For such a minor level of misalignment of the connectors when mated, it may well be that whilst not being fully/optimally mechanically mated, the mechanical connection is nevertheless sufficiently secure for intended purposes.

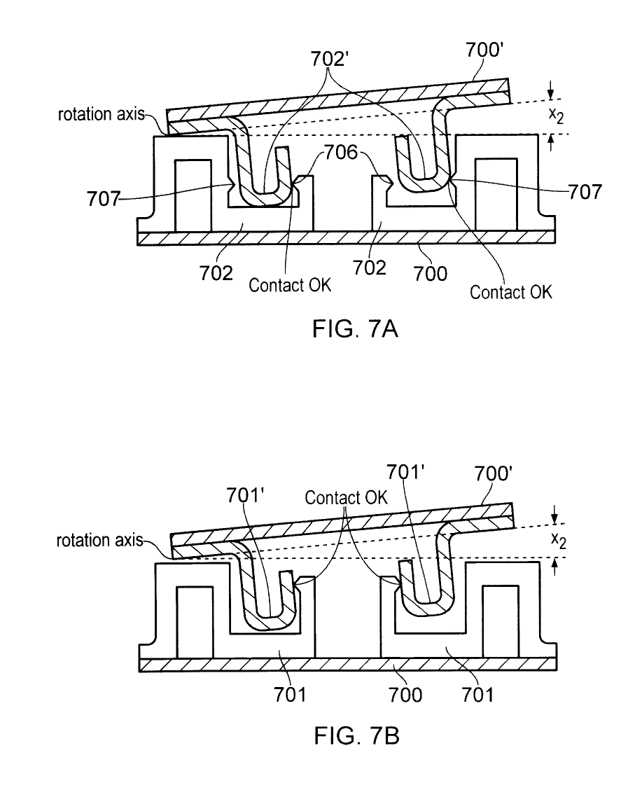

The embodiment of FIGS. 6A and 6B would thus provide an indication of an improper mate for small rotation angles what are at acceptable levels. It may well be that greater angles of rotation would still be sufficiently mechanically acceptable. In order the prevent false negative determinations of an improper mechanical connection under such a scenario, each detection pin is provided with a further electrical connection point 707 as shown in the embodiment of FIGS. 7A and 7B.

FIGS. 7A and 7B provide cross sectional side-on views similar to that of FIGS. 6A and 6B, wherein the first connector 700 and the second connector 700′ are again in a third mated condition (i.e. a mated condition that, whilst not fully/optimally mated is nevertheless sufficiently mechanically mated and secure). In this embodiment however, the rotation angle is x2 which is still less than 5 degrees but is slightly greater than x1 of FIGS. 6A and 6B, for example x2 may be 4.4 degrees. Also, each detection pin 702 is now provided with a second electrical contact point 707 in addition to its first electrical contact point 706. Both of these contacts points are at the same height.

In FIG. 7B, both signal pins 701 are in electrical contact with their respective pins 701′ of the second connector 700′ as indicated by “contact ok”. Likewise, as shown in FIG. 7A, both detection pins 702 are in electrical contact with their respective pins 702′ “contact ok”. Whilst the left-hand side detection pin 702 is in electrical contact with respective pin 702′ via its first electrical contact 706, the right-hand sign detection pin 702 is in electrical contact with respective pin 702′ via its second electrical contact 707. Since the detection pins are electrically connected to their respective pins, this would indicate an acceptable mechanical mate. The detection pins 702 are configured such that, should the mated condition become further misaligned (i.e. the rotation angle exceed a predetermined amount, e.g. greater than 5 degrees) electrical connection to their respective pin 702′ would cease.

Accordingly, the embodiment of FIGS. 7A and 7B provide a connector wherein the detection pin has a first electrical contact point 706 and a second electrical contact point 707,

wherein the first electrical contact point is configured:
to electrically couple with its respective pin of a second connector when in a first mated condition (i.e. a fully/optimal mate), and
to electrically decouple from its respective pin when in a third mated condition (i.e. a partial mate which is nevertheless sufficiently secure); and

wherein the second electrical contact point is configured:
to electrically couple with its respective spin in the third mated condition, and
to electrically decouple from its respective pin when in a second mated condition (i.e. an insufficiently secure mate).

Advantageously, providing more than one electrical contact point on the detection pins provides greater leeway and more tolerance of the degree of mechanical connection that would otherwise lose electrical connection of the detection pins resulting in a determination of an improper mechanical mate.

FIG. 8 schematically illustrates an apparatus of a further embodiment of the present invention. The first connector 800 is connected to, for example, a printed wired board or a flexible printed circuit 803. The second connector 800′ is connected to, for example, a touch module, a display module or UI module 803′. The 2×7 array of signal pins, when mated to the second connector, provide signal pathways from the PWB/FPC to the module. The first connector 800 is provided with four detection pins. The second connector 800′ may be a standard board to board connector with no detection pins.

A detection pin 802 of a first row of the connector 800 is connected to a detection system 810. The other detection pin of the first row is connected to a detection pin of the last row of the connector. The other detection pin 802 of the last row is also connected to the detection system 810. The respective pins 802′ of the first row of the second connector 800′ are electrically connected together, for example via circuitry in the module 803′. Likewise, the respective pins 802′ of the last row of the second connector 800′ are electrically connected together. Such an arrangement forms a detection circuit enabling the determination of whether or not the detection pins 802 are electrically connected to their respective pins 802′ in order to determine whether or not the connectors are sufficiently mechanically mated with one another.

The detection pins may be dedicated to testing the condition of the mechanical assembly of the connectors, whilst the other pins of the connector are used to carry power/data signals between the PCB/PWD and module. However, it is possible for the detection pins, in addition to being used in a detection circuit, to be also used as a signal pin to carry power/data signals.

FIG. 9 schematically illustrates a flow chart of method blocks of a method 900 of an embodiment of the present invention.

Block 901 involves testing an electrical connection between a detection pin of a first connector and its respective pin of another connecter when in a mated condition. For example, this might involve causing, at least in part actions, that result in testing an electrical connection between a second terminal of a first apparatus and a respective second terminal of a second apparatus, wherein:
the first apparatus comprises:
   a first terminal configured to electrically couple with a respective first terminal of the second apparatus when the first apparatus and the second apparatus are in either of a first mated condition and a second mated condition; and wherein
   the second terminal is configured:
      to electrically couple with the respective second terminal of the second apparatus when the apparatus and the second apparatus are in the first mated condition, and
      to electrically decouple from the respective second terminal of the second apparatus when the first apparatus and the second apparatus are in a second mated condition.

Block 902 involves determining whether or not a mechanical connection between the first and second connectors is acceptable based on a result of the test.

The blocks illustrated in FIG. 9 may represent steps in a method and/or sections of code in a computer program.

It will be understood that each block and combinations of blocks of FIG. 9 can be implemented by various means, such as hardware, firmware, and/or software including one or more computer program instructions. For example, one or more of the procedures may be embodied by computer program instructions. In this regard, the computer program instructions which embody the procedures described above may be stored by a memory storage device and executed by a processor. As will be appreciated, any such computer program instructions may be loaded onto a computer or other programmable apparatus (i.e. hardware) to produce a machine, such that the instructions which execute on the programmable apparatus create means for implementing the functions specified in the blocks. These computer program instructions may also be stored in a computer-readable medium that can direct a programmable apparatus to function in a particular manner, such that the instructions stored in the computer-readable memory produce an article of manufacture including instruction means which implement the function specified in the blocks. The computer program instructions may also be loaded onto a programmable apparatus to cause a series of operational steps to be performed on the programmable apparatus to produce a computer-implemented process such that the instructions which execute on the programmable apparatus provide steps for implementing the functions specified in the blocks.

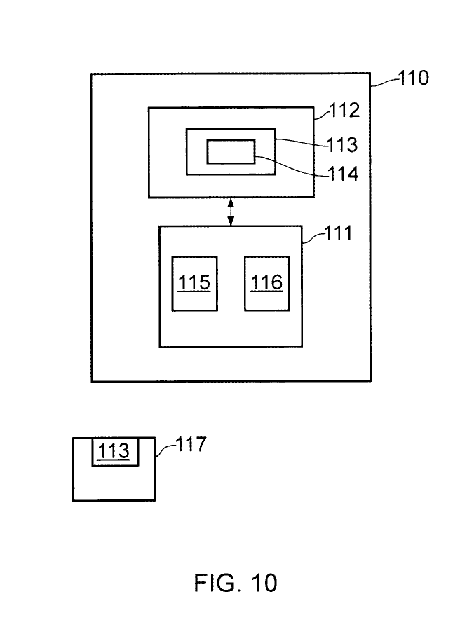

FIG. 10 schematically illustrates an apparatus 110 for running computer program instructions as mentioned above to effect the method shown in FIG. 9.

Within such an apparatus, one or more connectors as described above may be used (not shown). Additionally, a detection circuit, such as described with reference to FIG. 8, may also be provided.

In one embodiment, the apparatus 110 is embodied on a hand held portable electronic device, such as a mobile telephone, personal digital assistant, or tablet, that may additionally provide one or more audio/text/video communication functions (e.g. tele-communication, video-communication, and/or text transmission (Short Message Service (SMS)/ Multimedia Message Service (MMS)/emailing) functions), interactive/non-interactive viewing functions (e.g. web-browsing, navigation, TV/program viewing functions), music recording/playing functions (e.g. Moving Picture Experts Group-1 Audio Layer 3 (MP3) or other format and/or (frequency modulation/amplitude modulation) radio broadcast recording/playing), downloading/sending of data functions, image capture function (e.g. using a (e.g. in-built) digital camera), and gaming functions.

The apparatus 110 comprises: at least one processor 111 which is configured to read from and write to a memory 112.

The memory 112 stores a computer program 113 comprising computer program instructions 114 that control the operation of the apparatus 110 when loaded into the processor 111. The computer program instructions 114 provide the logic and routines that enables the apparatus to perform the methods illustrated in FIG. 9. The processor by reading the memory is able to load and execute the computer program such that an electrical test can be performed to determine whether or not the connectors are correctly/adequately mechanically mated.

The processor may also comprise an output interface 115 via which data and/or commands are output by the processor 111 and an input interface 116 via which data and/or commands are input to the processor.

References to computer program, instructions, code etc. should be understood to encompass software for a programmable processor or firmware such as, for example, the programmable content of a hardware device whether instructions for a processor, or configuration settings for a fixed-function device, gate array or programmable logic device etc.

In the above description, the wording ‘connect’ and ‘couple’ and their derivatives mean operationally connected/coupled. It should be appreciated that any number or combination of intervening components can exist (including no intervening components).

Although functions have been described with reference to certain features, those functions may be performable by other features whether described or not.

Features described in the preceding description may be used in combinations other than the combinations explicitly described.

Although features have been described with reference to certain embodiments, those features may also be present in other embodiments whether described or not.

Although various embodiments of the present invention have been described in the preceding paragraphs with reference to various examples, it should be appreciated that modifications to the examples given can be made without departing from the scope of the invention as claimed.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

1-21. (canceled)

22. An apparatus comprising:
a first terminal ; and
a second terminal ;
wherein:
the first terminal is configured to electrically couple with a respective first terminal of a second apparatus when the apparatus and said second apparatus are in either of a first mated condition and a second mated condition; and
the second terminal is configured:
to electrically couple with a respective second terminal of said second apparatus when the apparatus and said second apparatus are in the first mated condition, and
to electrically decouple from said respective second terminal of said second apparatus when the apparatus and said second apparatus are in a second mated condition.

23. An apparatus as claimed in claim 22, wherein the dimensions of the second terminal are different to the dimensions of the first terminal.

24. An apparatus as claimed in claim 23, wherein the first mated condition corresponds to a sufficiently secure mechanical mate and the second mated condition corresponds to an insufficiently secure mechanical mate.

25. An apparatus as claimed in claim 24, further comprising a detector configured to detect an electrical connection between the second terminal and its said respective second terminal of said second apparatus.

26. An apparatus as claimed in claim 24 further comprising a detector configured to detect an electrical connection between the second terminal and its said respective second terminal of said second apparatus wherein the presence of an electrical connection corresponds to the first mated condition and the absence of an electrical connection corresponds to the second mated condition.

27. An apparatus as claimed in claim 22, further comprising a plurality of first terminals and second terminals.

28. An apparatus as claimed in claim 27, wherein the dimensions of each terminal of the plurality of first terminals is substantially uniform.

29. An apparatus as claimed in claim 28, wherein each terminal of the plurality of first terminals comprises an electrical contact point, and wherein each electrical contact point is located substantially along a first plane.

30. An apparatus as claimed in claim 29 wherein:
each terminal of the plurality of second terminals comprises an electrical contact point, and each electrical contact point is located substantially along a second plane different to the first plane.

31. An apparatus as claimed in claim 22, wherein the first mated condition corresponds to a sufficiently secure mechanical mate and the second mated condition corresponds to an insufficiently secure mechanical mate.

32. An apparatus as claimed in claim 22, wherein the second terminal has a first electrical contact point and a second electrical contact point wherein the first electrical contact point is configured:
to electrically couple with said respective second terminal of said second apparatus when the apparatus and said second apparatus are in the first mated condition, and
to electrically decouple from said respective second terminal of said second apparatus when the apparatus and said second apparatus are in a third mated condition; and
wherein the second electrical contact point is configured:
to electrically couple with said respective second terminal of said second apparatus when the apparatus and said second apparatus are in the third mated condition, and
to electrically decouple from said respective second terminal of said second apparatus when the apparatus and said second apparatus are in a second mated condition.

33. An apparatus as claimed in claim 27, wherein at least two of the plurality of second terminals are configured so as to be electrically connected to one another.

34. An apparatus as claimed in claim 22, further comprising a detector to detect an electrical connection between the second terminal and its said respective second terminal of said second apparatus.

35. An apparatus as claimed in claim 31, wherein the apparatus comprises a connector for electrical connection.

36. A device comprising an apparatus as claimed in claim 22.

37. A method comprising:
causing, at least in part, actions that result in testing an electrical connection between a second terminal of a first apparatus and a respective second terminal of a second apparatus, wherein:
the first apparatus comprises:
a first terminal configured to electrically couple with a respective first terminal of the second apparatus when the first apparatus and the second apparatus are in either of a first mated condition and a second mated condition; and wherein
the second terminal is configured:
to electrically couple with the respective second terminal of the second apparatus when the apparatus and the second apparatus are in the first mated condition, and to electrically decouple from the respective second terminal of the second apparatus when the first apparatus and the second apparatus are in a second mated condition.

38. A method as claimed in claim 27, further comprising determining an acceptability of a mechanical connection between the first and second apparatus based on the test.

39. An apparatus comprising:
a first means for electrically coupling with a respective first electrically conductive means of a second apparatus when the apparatus and said second apparatus are in either of a first mated condition and a second mated condition; and
a second means for electrically coupling with a respective second electrically conductive means of said second apparatus when the apparatus and said second apparatus are in the first mated condition, and wherein
the second means is configured to electrically decouple from said respective second electrically conductive means of said second apparatus when the apparatus and said second apparatus are in the second mated condition.
